(19) United States
(12) Patent Application Publication
(10) Pub. No.: US 2011/0241790 A1
(43) Pub. Date: Oct. 6, 2011

(54) Tuning-Fork Type Crystal Vibrating Piece Device and Manufacturing the Same

(76) Inventor: Yoshiaki Amano, Sayama-shi (JP)

(21) Appl. No.: 13/070,856

(22) Filed: Mar. 24, 2011

(30) Foreign Application Priority Data
Mar. 30, 2010 (JP) 2010-076503

(51) Int. Cl. H03B 5/32; H01L 41/22

(52) U.S. Cl. 331/156; 29/25.35

(57) ABSTRACT

A method for manufacturing a piezoelectric device comprising steps of preparing a base wafer (S122, S124) having a plurality of bases having a first bonding film formed on surrounding of the bases and first dents (66) formed adjacent to and contacted to the first bonding film; preparing a lid wafer (S102, S104) having a plurality of lids having a second bonding film formed on surrounding of the lid and the second dents (67) formed adjacent to and contacted to the second bonding film; mounting a bonding material (75) on the first dents (66) or the second dents (67); and bonding (S152) the base wafer and the lid wafer by solidifying the bonding material after melting the bonding material and flowing the molten material along the first bonding film and the second bonding film.

### CROSS-REFERENCE TO RELATED APPLICATION

This application claims priority to and the benefit of Japan Patent Application No. 2010-076503 filed on Mar. 30, 2010 in the Japan Patent Office, the disclosure of which is incorporated herein by reference in its entirety.

### FIELD

The present invention relates to a method for manufacturing a tuning-fork type quartz vibrating piece with a pair of vibrating arms, and a quartz device having the tuning-fork type quartz vibrating piece.

### DESCRIPTION OF THE RELATED ART

When the tuning-fork type quartz vibrating piece is miniaturized, a CI value (crystal impedance) or equivalent series resistance becomes large. Then, a technology of forming grooves in front and rear faces of the vibrating arms of the tuning-fork type quartz vibrating piece was proposed, as in U.S. Pat. No. 6,911,765. In the tuning-fork type quartz vibrating piece of U.S. Pat. No. 6,911,765, an increase of the CI value of the tuning-fork type quartz vibrating piece can be held down. On the other hand, there arises a problem that when the grooves including its bottom face and side faces are formed on the front and rear faces of the vibrating arms and excitation electrodes are formed on the bottom face and the side faces, disconnection etc. occurs in the excitation electrodes at positions where the front and rear faces of the vibrating arms bend to the side faces by an angle of 90 degrees.

In Japan Laid Open 2003-133895, in order to solve this problem, a width of the grooves is made narrower as a base side of the grooves approaches nearer to the base so that the angle may vary gradually from the front and rear faces of the vibrating arms to the side faces, respectively. By adopting such a shape of the grooves, the angles from the front and rear faces of the vibrating arms to the side faces are made gradual.

Generally, in order to reduce the CI value, it is necessary to make the depth of the grooves in the vibrating arms equal to or deeper than a constant value. Therefore, etching for forming the grooves needs to be performed for a fixed time or longer. However, in the case where the etching was performed so that a shape of the opening in the grooves might be narrower as the location approached nearer to the base side, there was a problem that when the fixed time elapsed, the angles from the front and rear faces of the vibrating arms in the grooves to the side faces became close to 90 degrees.

### SUMMARY

It is an object of the present invention to provide a method for manufacturing a tuning-fork type quartz vibrating piece having gradual angles from the front and rear faces of the vibrating arms to the side faces.

A method for manufacturing a tuning-fork type quartz vibrating piece of a first aspect comprises a photolithography step of applying a resist to an anticorrosion film formed on the quartz material, and exposing a region thereof that corresponds to the base, the vibrating arms, and the grooves by exposing the resist. The method comprises a first etching step of forming an outline of the tuning-fork type quartz vibrating piece by etching the anticorrosion films other than the region that corresponds to the base, the vibrating arms, and the groves and by etching the quartz material; a removal step of removing the anticorrosion film and the resist that remain on the quartz material; and a second etching step of etching at least one of a first fork part formed between the one pair of vibrating arms and the base, and a base-side end face of the grooves by immersing the quartz material in an etchant after the removal step.

A method for manufacturing a tuning-fork type quartz vibrating piece of a second aspect is that the first etching step and the second etching step use the same temperature and the same etchant, and an etching time of the second etching step is shorter than an etching time of the first etching step.

A method for manufacturing a tuning-fork type quartz vibrating piece of a third aspect is that he whole front and rear faces of the tuning-fork type quartz vibrating piece exposed by the removal process are immersed in the etchant.

A method for manufacturing a tuning-fork type quartz vibrating piece of a fourth aspect is that at least one of the first fork part and the end face in the tuning-fork type quartz vibrating piece is covered with a mask and is immersed in the etchant.

A piezoelectric device having a package having a cavity for storing the tuning-fork type piezoelectric vibration piece manufactured according to anyone of the above first aspect through the fourth aspect.

A piezoelectric device that is equipped with a lid plate having a first recess part and a base plate having a second recess part and sandwiches the tuning-fork type piezoelectric vibrating piece manufactured by any one of above first aspect through the fourth aspect with the lid plate and the base plate.

According to the present invention, it is possible to provide a method for manufacturing the tuning-fork type quartz vibrating piece having gradual angles from the front and rear faces of the vibrating arms to the base-side end faces of the fork part or the grooves. Moreover, since light in a photolithography process is exposed onto the fork part or the end faces having gradual angles, there does not occur a problem that an unnecessary metal film remains and thereby an electrical short circuit arises.

### BRIEF DESCRIPTION OF THE DRAWINGS

FIG. 1 is a perspective view of the first tuning-fork type crystal vibrating piece 10A.

FIG. 2 is a cross-section along the line A-A line of FIG. 1.

FIG. 3 is a cross-section along the line B-B of FIG. 1.

FIG. 4 is an enlarged flat view of a part surrounded by a dotted-line C of FIG. 1 seen from the +Z side.

FIG. 6 is a flow chart showing a manufacturing method of the first tuning-fork type crystal vibrating piece 10A.

FIG. 7 is a flat view of a half-finished first tuning-fork type crystal vibrating piece 10A-s.

FIG. 8A is a flat view showing a circular crystal wafer 20-1 that forms a profile of first tuning-fork type crystal vibrating piece 10A.

FIG. 8B is a flat view showing a rectangular crystal wafer 20-2 that forms a profile of first tuning-fork type crystal vibrating piece 10A.

FIG. 9 is a flat view of the second tuning-fork type crystal vibrating piece 10B.

FIG. 10 is an enlarged view of a part surrounded by the dotted line G of FIG. 9.

FIG. 12 is a flat view showing a half-finished second tuning-fork type crystal vibrating piece 10B-s in a first variation example.

FIG. 11 is a flat view of the third tuning-fork type crystal vibrating piece 10C.

FIG. 13 is a flat view showing a half-finished third tuning-fork type crystal vibrating piece 10C-s in a second variation example.

FIG. 14 is a flat view showing the fourth tuning-fork type crystal vibrating piece 10D of a third variation example.

FIG. 15 is a flat view showing the fifth tuning-fork type crystal vibrating piece 10E of a fourth variation example.

FIG. 16A is a side view of the piezoelectric oscillator 100 comprising the first tuning-fork type piezoelectric vibrating piece 10A.

FIG. 16B is a side view of the piezoelectric oscillator 200 comprising the fourth tuning-fork type piezoelectric vibrating piece 10D.

FIG. 17A is an exploded perspective view of the piezoelectric oscillator 300 comprising the fifth tuning-fork type piezoelectric vibrating piece 10E.

FIG. 17B is a cross-sectional view along the line K-K of the piezoelectric oscillator 300 comprising the fifth tuning-fork type piezoelectric vibrating piece 10E.

### DETAILED DESCRIPTION

Each embodiment of the present invention will be explained below by referring figures.

In the following embodiments, a direction where a vibrating arm extends along a crystal axis of the crystal is a Y-axis direction, a direction of the width of vibrating arm is an X-axis direction, and a direction perpendicular to the X-axis and the Y-axis is a Z-axis.

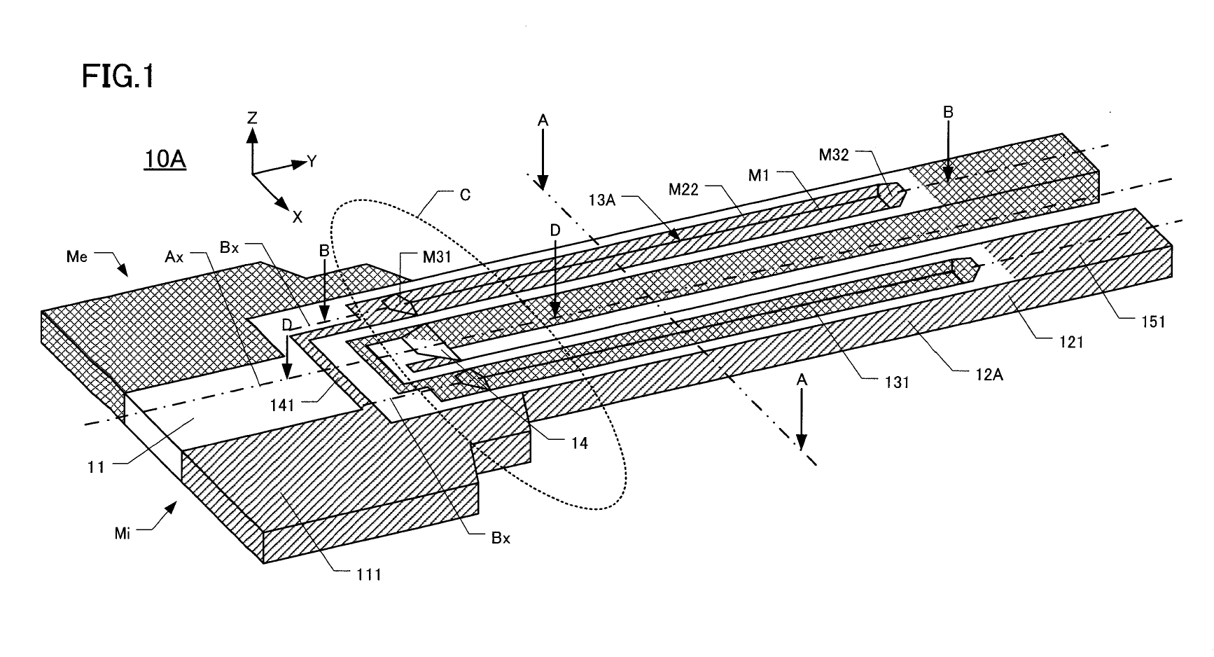

### First Embodiment

<Entire Configuration of the First Tuning-Fork Type Quartz Vibrating Piece 10A> FIG. 1 is a perspective view of a first tuning-fork type quartz vibrating piece 10A. Incidentally, in FIG. 1, a +Z side face of the first tuning-fork type quartz vibrating piece 10A is designated as a “front face Me” and a −Z side face thereof is designated as a “rear face Mi.” Since in the first tuning-fork type quartz vibrating piece 10A, a shape seen from the front face Me and a shape seen from the rear face Mi are the same, its explanation will be given taking a perspective view of the first tuning-fork type quartz vibrating piece 10A seen from the front face Me as one example. Similarly, also in a plan view referred to henceforth, its explanation will be given taking only a plan view seen from the front face Me as one example.

The first tuning-fork type quartz vibrating piece 10A shown in FIG. 1 vibrates, for example, at 32.768 kHz, and is extremely miniaturized. For example, the first tuning-fork type quartz vibrating piece 10A measures about 1.7 mm in whole length in a Y-axis direction, about 0.5 mm in whole width in an X-axis direction, and about 0.4 mm in width in a Z-axis direction. Moreover, the first tuning-fork type quartz vibrating piece 10A has a base 11 of an almost rectangular shape and a pair of vibrating arms 12A extending from the base 11 in the +Y-axis direction. Furthermore, widened parts (not illustrated) whose widths in the X-axis direction are designed to be larger than the vibrating arms 12A may be formed on +Y side distal ends of the one pair of vibrating arms 12A, respectively. The widened parts enable the one pair of vibrating arms 12A of the first tuning-fork type quartz vibrating piece 10A to vibrate easily.

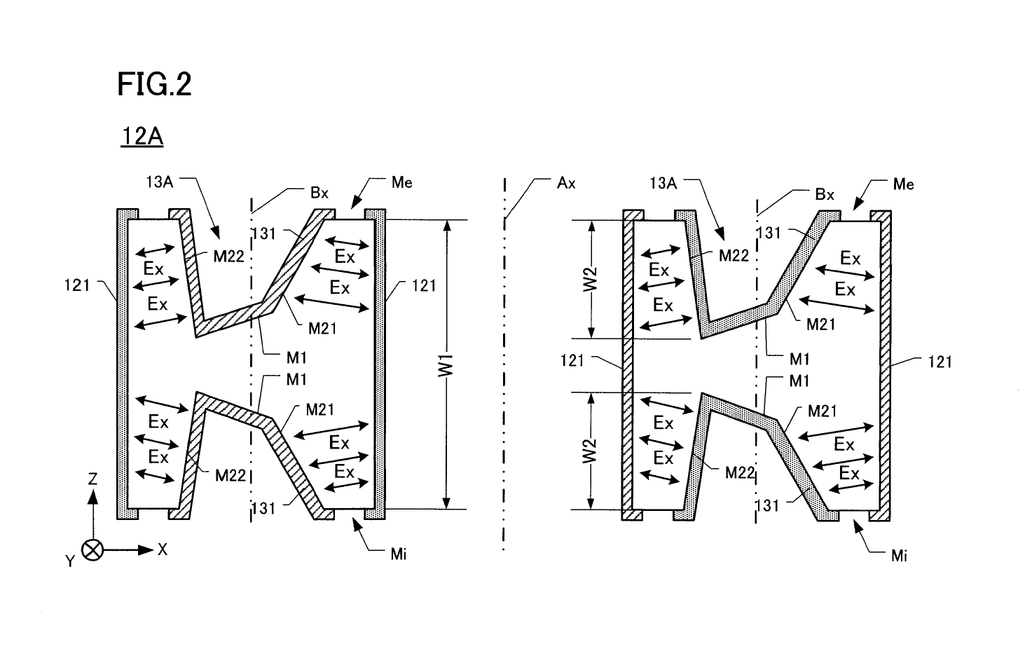

Since grooves 13A that are recessed from the front face Me and the rear face Mi of the one pair of vibrating arms 12A and extend in the Y-axis direction are formed on the front face Me and the rear face Mi thereof, respectively, A-A cross-sectional views of the vibrating arms 12A are almost H-shaped (see FIG. 2). The grooves 13A will be explained in detail in following FIG. 2 to FIG. 4.

Base electrodes 111 of a rectangular shape whose polarities are different from each other (shown by a slashed portion and a netted portion in FIG. 1) are formed on both corners of a −Y side of the base 11, respectively. Grooves excitation electrodes 131 whose polarities are different from each other are formed in the one pair of the grooves 13A, respectively. Moreover, side face excitation electrodes 121 of the same polarity are formed on both outsides of the −X side vibrating arm 12A in the X-axis direction, respectively, and side face excitation electrodes 121 of a polarity different from that of the side face excitation electrodes 121 of the −X side vibrating arm 12A are formed on both outsides of the +X side vibrating arm 12A in the X-axis direction, respectively. Metal films 151 to which the side face excitation electrodes 121 on both outsides of the vibrating arms 12A are to be connected are formed at the +Y-axis side distal ends of the one pair of vibrating arms 12A, respectively.

The base electrode 111 is connected to the side face excitation electrode 121 and to the grooves excitation electrode 131 through a connection electrode 141, respectively. With this configuration, the base electrode 111 conducts electricity to the side face excitation electrode 121 and to the grooves excitation electrode 131. When the base electrode 111 is connected to an external electrode 118 (see FIG. 16A) through an electrically conductive adhesive 116 (see FIG. 16A), the external electrode 118 conducts electricity to the side face excitation electrode 121 and to the grooves excitation electrode 131, respectively, which excites the vibrating arms 12A of the first tuning-fork type quartz vibrating piece 10A.

Each electrode pattern has a configuration where a gold (Au) layer of a thickness of 200 Å to 3000 Å is formed on a chromium (Cr) layer of a thickness of 50 Å to 700 Å. Instead of the chromium (Cr) layer, a tungsten (W) layer, a nickel (nickel) layer, or a titanium (Ti) layer may be used, and a silver (Ag) layer may be used instead of the gold (Au) layer.

<Configuration of the Grooves 13A> As shown in FIG. 1, each of the one pair of the grooves 13A has a bottom face M1, and a first long side face M21 (see FIG. 2), a second long side face M22, a first short side face M31, and a second short side face M32 that are connected to the bottom face M1. Incidentally, the first long side face M21 (see FIG. 2) extending in the Y-axis direction is provided on a +X side of the bottom face M1, and the second long side face M22 extending in the Y-axis direction is provided on a −X side of the bottom face M1. The first short side face M31 is provided on a −Y side of the bottom face M1, and the second short side face M32 is provided on a +Y side of the bottom face M1.

FIG. 2 is an A-A cross-sectional view of FIG. 1. Since the grooves 13A are formed to be recessed from the front face Me and the rear face Mi of the first tuning-fork type quartz vibrating piece 10A, as shown in FIG. 2, the A-A cross-sectional view of the vibrating arms 12A becomes almost H-shaped. Moreover, in FIG. 2, the grooves 13A are formed by wet etching so that its width may become narrower toward the center starting from the front face Me and the rear face Mi of the first tuning-fork type quartz vibrating piece 10A in the Z-axis direction. A depth W2 of the grooves 13A is about 35% to 45% of a thickness W1 of the first tuning-fork type quartz vibrating piece 10A.

Here, if an alternating voltage is impressed to the grooves excitation electrode 131 and the side face excitation electrode 121, an electric field Ex will occur along an arrow direction between the grooves excitation electrode 131 and the side face excitation electrode 121. Since this electric field Ex works perpendicularly to the electrodes in the vibrating arms 12A, i.e., linearly, the electric field Ex becomes large. As a result, even in the case where the first tuning-fork type quartz vibrating piece 10A is miniaturized, a quartz vibrating piece with a small equivalent series resistance can be obtained.

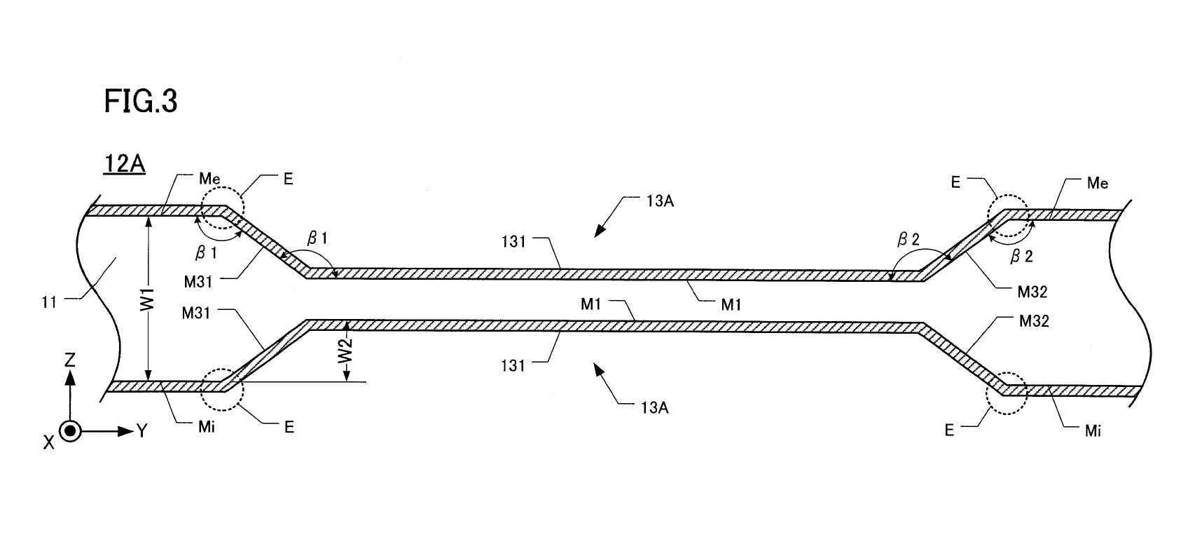

FIG. 3 is a B-B cross-sectional view of FIG. 1. The grooves 13A formed in the vibrating arms 12A are formed by the wet etching. The first short side face M31 on the base 11 side becomes a gentle slope formed to be inclined at a predetermined slope angel β1 to the front face Me or rear face Mi, and the second short side face M32 on the distal end side of the vibrating arm 12A becomes a gentle slope formed to be inclined at a predetermined slope angel β2 to the front face Me or rear face Mi. Here, it is desirable that the slope angle β1 is about 120° to 160°. The first short side face M31 becomes the gentle slope by being wet etched again after the grooves 13A are formed by the wet etching.

With such a configuration, when forming the grooves excitation electrode 131 in the grooves 13A, the photoresist can be applied in uniform thickness on a metal film for electrode in an edge portion E (a first short side S11, a second short side S12, and a third short side S13 that will be described later). Moreover, when forming the electrodes by photolithography, the metal film is susceptible to be irradiated by ultraviolet rays. Therefore, the completed electrode pattern has less occurrence of disconnection etc.

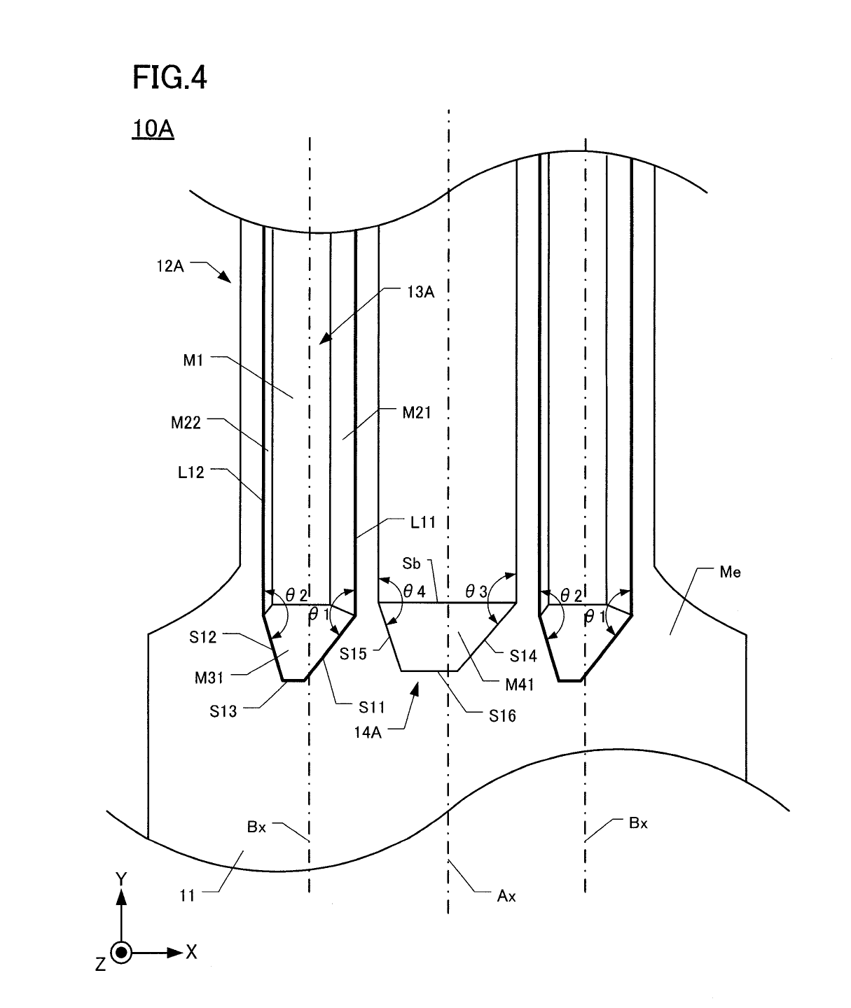

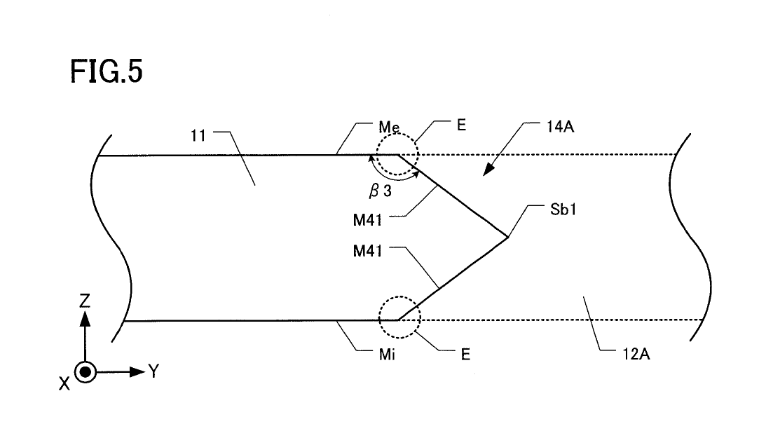

FIG. 4 is an enlarged plan view of a portion surrounded by a dotted line C of FIG. 1 seen from the +Z side. In order to make the drawing easy to see, each electrode is not drawn in FIG. 4. As shown in FIG. 4, the first long side face M21 and the front face Me intersect at a first long side L11 extending in the Y-axis direction, and the second long side face M22 and the front face Me intersect at a second long side L12 extended in the Y-axis direction. The first short side face M31 and the front face Me intersect at the first short side S11 connected to the first long side L11, intersect at the second short side S12 connected to the second long side L12, and intersect at the third short side S13 that links the first short side S11 and the second short side S12 and extends in the X-axis direction.

Here, a first angle θ1 made by the first long side L11 and the first short side S11 is smaller than a second angle θ2 made by the second long side L12 and the second short side S12.

<Configuration of the First Fork Part 14A> Below, a first fork part 14A will be explained in detail referring to FIG. 4 and FIG. 5. As shown in FIG. 4, the first fork part 14A consists of the one pair of the vibrating arms 12A and the base 11.

FIG. 5 is a D-D cross-sectional view of FIG. 1. The first fork part 14A shown in FIG. 5 has two fork part faces M41 extending obliquely from the front face Me and the rear face Mi to the center of the Z-axis direction, and a first boundary side Sb formed so that these two fork part faces M41 may intersect at an almost central position of the first tuning-fork type quartz vibrating piece 10A in a thickness direction. Here, it is desirable that the slope angle β3 that the fork part face M41 makes with the front face Me and the rear face Mi is about 120° to 160°, The fork part face M41 becomes a gentle slope by being wet etched again after the first fork part 14A is formed by the wet etching.

With such a configuration, when forming the connection electrode 141 in the first fork part 14A, a photoresist can be applied in uniform thickness on the metal film for electrode in the edge portion E (the first fork part side S14, the second fork part side S15, and the third fork part side S16 that will be described later) and it is easy to irradiate ultraviolet rays of photolithography. Therefore, the completed electrode pattern has less occurrence of disconnection etc.

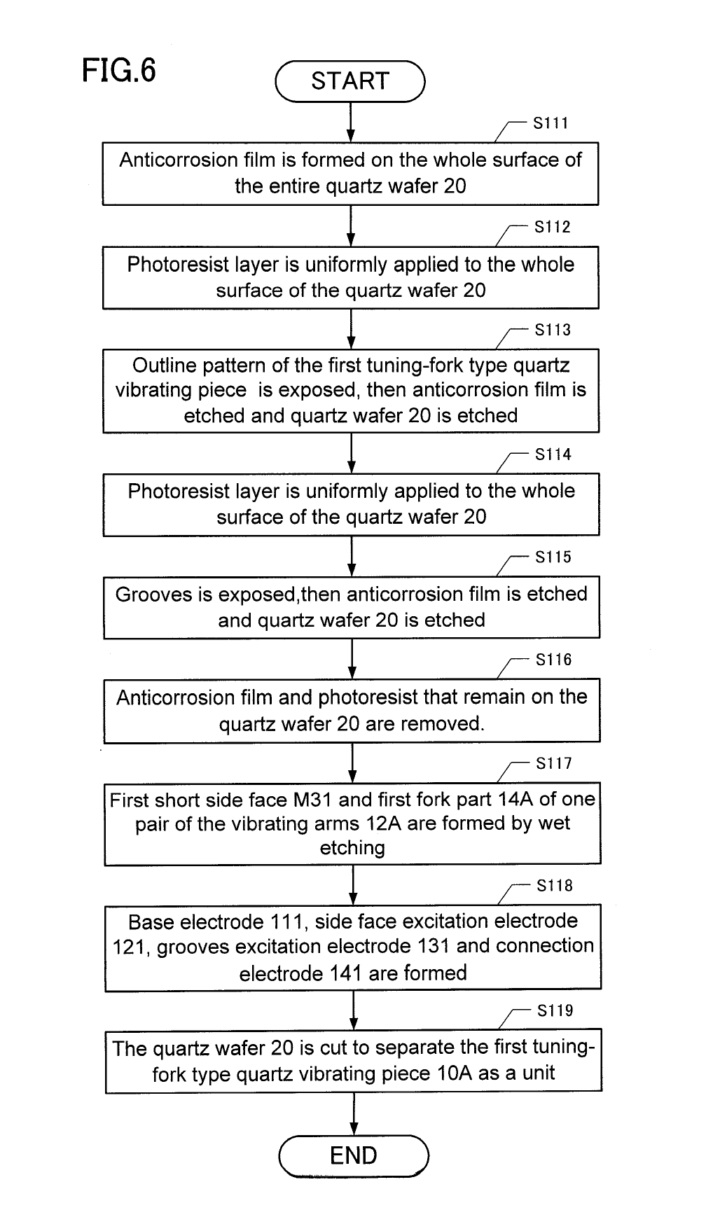

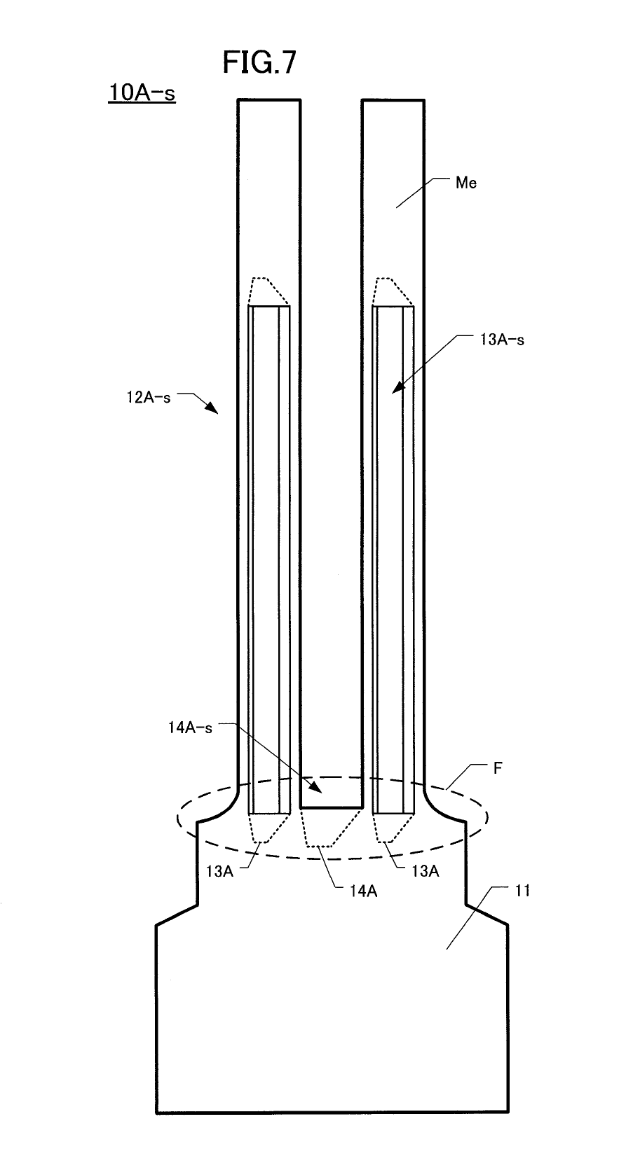

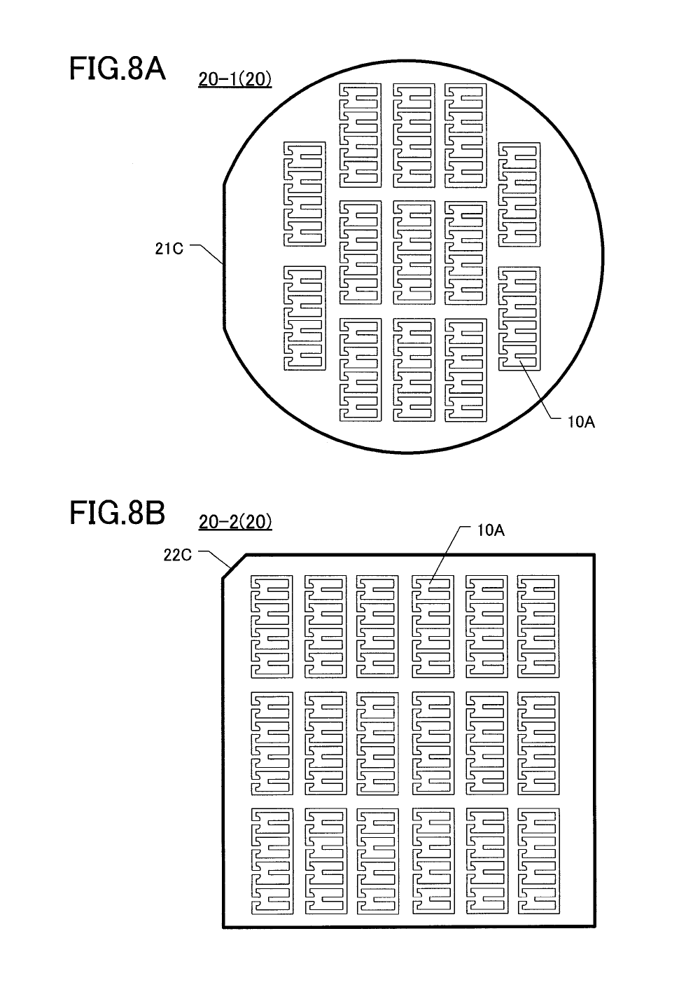

Returning to FIG. 4, the first fork part 14A will be explained continuously. The fork part face M41 and the front face Me intersect at the first fork part side S14, at the second fork part side S15, and at the third fork part side S16. Here, a first obtuse angle θ3 made by the first fork part side S14 and the Y-axis is smaller than a second obtuse angle θ4 made by the second fork part side S15 and the Y-axis.

<Manufacture Method of the First Tuning-Fork Type Quartz Vibrating Piece 10A> A manufacture method of the first tuning-fork type quartz vibrating piece 10A will be explained referring to FIG. 6 to FIG. 8. FIG. 6 is a flowchart showing the manufacture method of the first tuning-fork type quartz vibrating piece 10A. FIG. 7 is a plan view showing a semifinished product of the first tuning-fork type quartz vibrating piece 10A-s. FIG. 8A is a plan view showing a circular quartz wafer 20-1 that forms an outline of the first tuning-fork type quartz vibrating piece 10A; FIG. 8B is a plan view showing a rectangular quartz wafer 20-2 that forms the outline of the first tuning-fork type quartz vibrating piece 10A.

In Step S111 shown in FIG. 6, first, a z-cut quartz wafer 20 (see FIG. 8, however, FIG. 8 illustrates a wafer after the first tuning-fork type quartz vibrating piece 10A was formed) is prepared. Here, the quartz wafer 20 is a wafer of a circular or rectangular shape and is polished to a mirror finished surface. Then, a metal film acting as an anticorrosion film is formed on the whole surface of the entire quartz wafer 20 with a technique of sputtering, vapor deposition, or the like. A metal film such that a gold (Au) layer is deposited on a chromium (Cr) layer is used as the anticorrosion film.

In Step S112, a photoresist layer is uniformly applied to the whole surface of the quartz wafer 20 on which the anticorrosion film was formed, by a technique of spin coat etc. As the photoresist layer, for example, a positive photoresist by a novolac resin is used.

In Step S113, using an exposure apparatus (not illustrated), an outline pattern of the first tuning-fork type quartz vibrating piece 10A drawn on a photomask is exposed to both surfaces of the quartz wafer 20 to which the photoresist layers were applied. The exposed photoresist is removed by being developed. The gold layer etched from the photoresist layer is etched with respect to the gold layer, for example, using an aqueous solution of iodine and potassium iodide. Subsequently, a chromium layer exposed by the gold layer being removed is etched, for example, using an aqueous solution of diammonium cerium nitrate and acetic acid. These wet etching processes should be done so that excessive portions may not be eroded by adjusting concentrations and temperatures of the aqueous solutions and times of immersion in the aqueous solutions. Then, the exposed quartz wafer 20 is wet etched by being immersed in a wet etchant so that the planar outline (without the grooves) of the first tuning-fork type quartz vibrating piece 10A may be formed. Here, by the wet etching to the quartz wafer 20, as shown by solid lines of FIG. 7, a semifinished product of the first fork part 14A-s such that an intersection side of the fork part and the front face Me is one straight line is formed.

In Step S114, the photoresist layer is uniformly applied to the whole surface of the quartz wafer 20 that was wet etched by a technique of spray etc.

In Step S115, using the exposure apparatus (not illustrated), a pattern of a semifinished product of the grooves 13A-s (see the solid lines of FIG. 7) drawn on the photomask is exposed on the both surfaces of the quartz wafer 20 to which the photoresist layer is applied. The pattern of the semifinished product of the grooves 13A-s drawn on the photomask is a rectangle seen from the Z-direction. Then, the gold layer exposed from the photoresist layer is wet etched. Subsequently, the chromium layer exposed from the photoresist layer is wet etched. Then, the exposed quartz wafer 20 is wet etched, and the semifinished product of the grooves 13A-s as shown by the solid lines of FIG. 7 is formed. Through the above steps, as shown by the solid lines of FIG. 7, the semifinished product of the first tuning-fork type quartz vibrating piece 10A-s that has the semifinished product of the grooves 13A-s and the semifinished product of the first fork part 14A-s is formed.

Next, in Step S116, the anticorrosion film and the photoresist that remain on the semifinished product of the first tuning-fork type quartz vibrating piece 10A-s are removed. Thereby, the whole semifinished product of the first tuning-fork type quartz vibrating piece 10A-s becomes a state where there exists no anticorrosion film.

In Step S117, the whole semifinished product of the first tuning-fork type quartz vibrating piece 10A-s is wet etched by being immersed in the wet etchant without a mask. Incidentally, although the etching is done using the same temperature and the same buffered hydrofluoric acid or hydrofluoric acid of Step S113 or S115 in Step S117, its etching time is shorter than an etching time of Step S113 or S115. Thereby, the whole semifinished product of the first tuning-fork type quartz vibrating piece 10A-s is etched, and the grooves 13A and the first fork part 14A become shapes shown in FIG. 4.

Here, the whole semifinished product of the first tuning-fork type quartz vibrating piece 10A-s is wet etched by being immersed in the wet etchant without a mask, but the grooves 13A and the first fork part 14A (see FIG. 4) shown by dotted lines of FIG. 7 may be formed using a mask made of rubber so that only a portion shown by a broken line F of FIG. 7 may be wet etched.

After undergoing the above process, the quartz wafers 20-1, 20-2 as shown by FIG. 8A or FIG. 8B are formed. Each of them shows a situation where 13 blocks of the first tuning-fork type quartz vibrating pieces 10A, each block consisting of four pieces 10A, are arranged in the circular quartz wafer 20-1. In the circular quartz wafer 20-1, an orientation flat 21C for specifying a crystal orientation of the quartz is formed in a part of a peripheral part of the quartz wafer 20-1 so that its axial direction can be specified. Incidentally, although 39 first tuning-fork type quartz vibrating pieces 10A are drawn on the quartz wafer 20-1 for convenience of explanation, practically, more than hundreds or thousands of the first tuning-fork type quartz vibrating pieces 10A are formed in the quartz wafer 20-1. The processing is also the same in the rectangular quartz wafer 20-2.

In Step S118, the quartz wafer 20 on which the grooves 13A and the first fork part 14A are formed is washed with pure water. Then, in order to form the base electrode 111, the side face excitation electrode 121, the grooves excitation electrode 131, the connection electrode 141, and the metal film 151 (see FIG. 1), the metal film for electrode of, for example, Au/Cr etc. is formed on the quartz wafer 20 by a technique of vapor deposition, sputtering, or the like. Then, the photoresist is uniformly applied to the metal film for electrode.

Here, by the wet etching in Step S117, the first short side face M31 (see FIG. 3) and the fork part face M41 (see FIG. 5) that become the gentle slopes are formed in the grooves 13A and the first fork part 14A, respectively. The photoresist can be applied to those edge portions E (see FIG. 3 and FIG. 5) in uniform thickness.

Next, the photomask corresponding to the each electrode pattern is prepared and the each electrode pattern is exposed onto the quartz wafer 20 to which the photoresist layer was applied. Here, the each electrode pattern is formed on both faces of the first tuning-fork type quartz vibrating piece 10A. Since the edge portion E (see FIG. 3 and FIG. 5) has an obtuse angle, ultraviolet rays are appropriately irradiated on the photoresist. After the photoresist layer is developed, the exposed photoresist layer is removed. The remaining photoresist becomes the photoresist layer corresponding to the electrode pattern. Furthermore, the wet etching of the metal film that becomes an electrode is performed. Thereby, the base electrode 111, the side face excitation electrode 121, the grooves excitation electrode 131, the connection electrode 141, and the metal film 151 (see FIG. 1) are formed on the front and rear faces of the first tuning-fork type quartz vibrating piece 10A. Since the edge portion E (see FIG. 3 and FIG. 5) has an obtuse angle, the electrode pattern without disconnection etc. is formed.

In Step S119, the quartz wafer 20 is cut by the dicing saw to separate the first tuning-fork type quartz vibrating piece 10A as a unit and the first tuning-fork type quartz vibrating piece 10A shown in FIG. 1 is completed.

### Second Embodiment

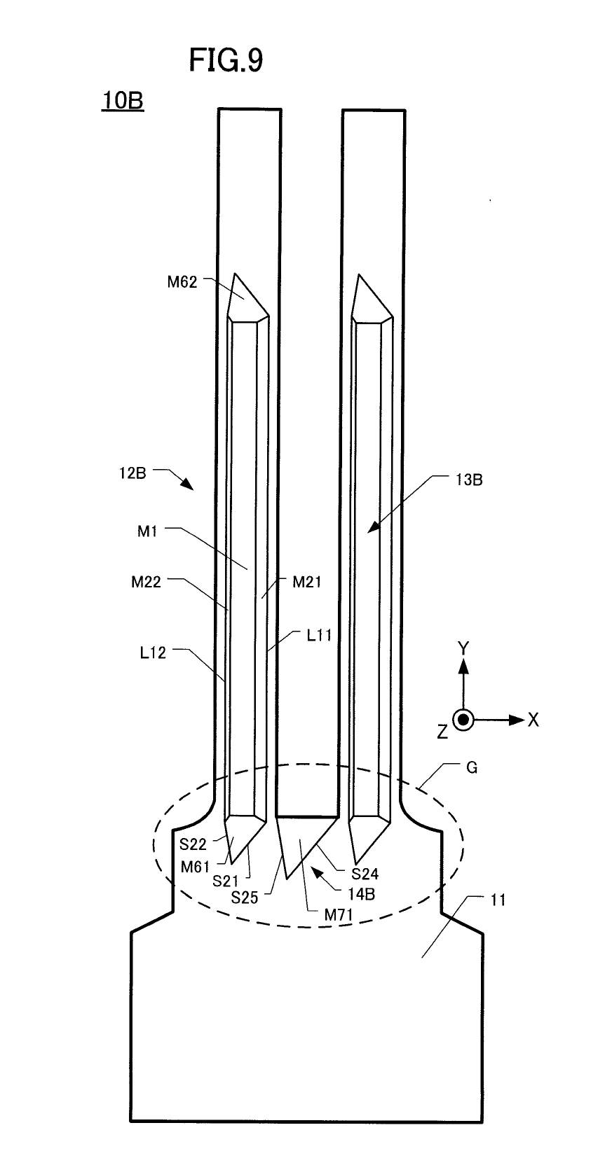

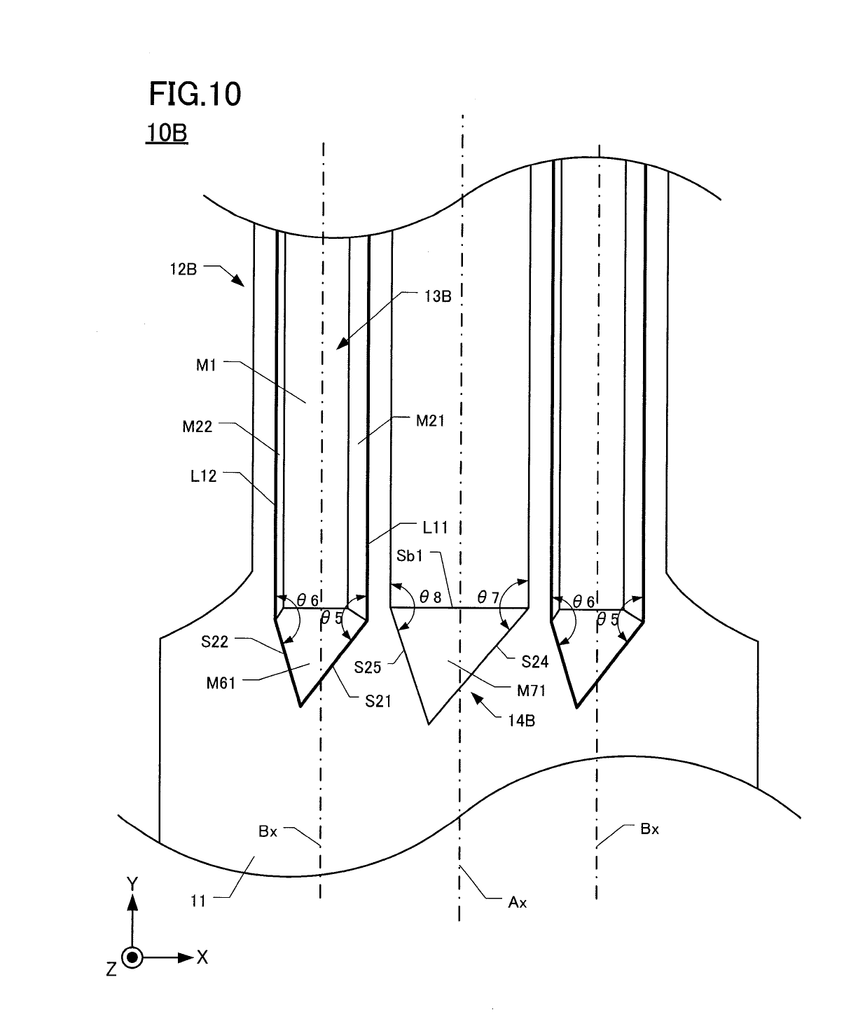

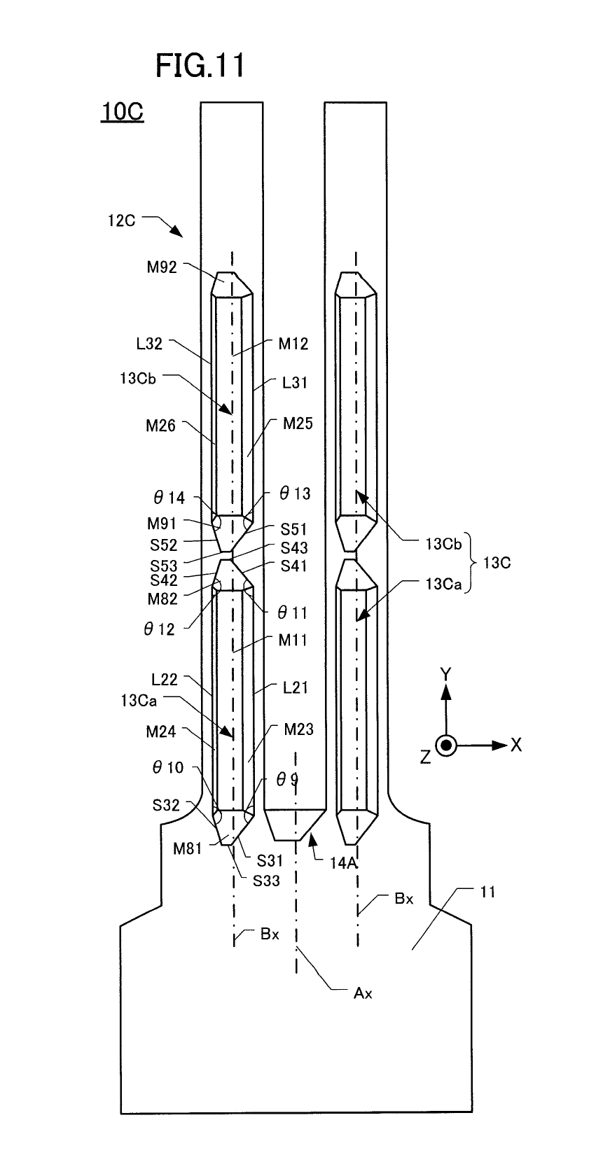

FIG. 9 shows a second tuning-fork type quartz vibrating piece 10B of a second embodiment. The second tuning-fork type quartz vibrating piece 10B is the same as that of the first embodiment in other portions except grooves 13B and a first fork part 14B. Below, the grooves 13B and the first fork part 14B of the second tuning-fork type quartz vibrating piece 10B will be explained referring to FIG. 9 and FIG. 10.

<Configuration of the Grooves 13B> FIG. 9 is a plan view of the second tuning-fork type quartz vibrating piece 10B. FIG. 10 is an enlarged view of a portion surrounded by a dashed line G of FIG. 9. In FIG. 9 and FIG. 10, electrodes are not illustrated to improve the clarity of the Figures.

First, each of the grooves 13B of vibrating arms 12B has the bottom face M1, and the first long side face M21, the second long side face M22, a first short side face M61 and a second short side face M62 that are connected to the bottom face M1. Incidentally, the first long side face M21 is provided on the +X side of the bottom face M1, extending along the Y-axis direction, and the second long side face M22 is provided on the −X side of the bottom face M1, extending along the Y-axis direction. The first short side face M61 is provided on the −Y side of the bottom face M1, and the second short side face M62 is provided on the +Y side of the bottom face M1.

The first long side face M21 and the front face Me intersect at the first long side L11 extending in the Y-axis direction, and the second long side face M22 and the front face Me intersect at the second long side L12 extending in the Y-axis direction. The first short side face M61 and the front face Me intersect at a first short side S21 connected to the first long side L11 and at a second short side S22 connected to the second long side L12.

As shown in FIG. 10, a first angle θ5 made by the first long side L11 and the first short side S21 is smaller than a second angle θ6 made by the second long side L12 and the second short side S22.

<Configuration of the First Fork Part 14B> As shown in FIG. 9, the first fork part 14B has two fork part faces M71 that extend from the front face Me and the rear face Mi to the center in the Z-axis direction, and the first boundary side Sb formed so that the two fork part faces M71 may intersect almost at the center in the thickness direction of the second tuning-fork type quartz vibrating piece 10B (see FIG. 5). The fork part face M71 and the front face Me intersect at a first fork part side S24 and a second fork part side S25.

As shown in FIG. 10, a first obtuse angle θ7 made by the first fork part side S24 and the Y-axis is smaller than a second obtuse angle θ8 made by the second fork part side S25 and the Y-axis.

<Manufacture Method of the Second Tuning-fork Type Quartz Vibrating Piece 10B> In the manufacture method of the second tuning-fork type quartz vibrating piece 10B, since other steps except Step S117 of FIG. 6 are the same as those of the manufacture method of the first tuning-fork type quartz vibrating piece 10A, only Step S117 will be explained.

In Step S117 shown in FIG. 6, the grooves 13B and the first fork part 14B shown in FIG. 9 are formed. Here, the whole second tuning-fork type quartz vibrating piece 10B may be wet etched by being immersed in the wet etchant without a mask, or the grooves 13b and the first fork part 14B may be formed by only a portion thereof being immersed in the wet etchant with a mask.

### Third Embodiment

FIG. 11 shows a third tuning-fork type quartz vibrating piece 10C of a third embodiment. The third tuning-fork type quartz vibrating piece 10C is the same as that of the first embodiment in other portions except the grooves 13C. Below, only the grooves 13C of the third tuning-fork type quartz vibrating piece 10C will be explained referring to FIG. 11.

<Configuration of the Grooves 13C> As shown in FIG. 11, the grooves 13C provided on a pair of vibrating arms 12C are formed, respectively, in such a manner that a first grooves unit 13Ca is on a −Y side thereof and a second grooves unit 13Cb is on a +Y side thereof separatedly. This configuration enables the strength of the one pair of vibrating arms 12C to be strengthened.

Explaining it in detail, the first grooves units 13Ca of the third tuning-fork type quartz vibrating piece 10C each have a bottom face M11, and a first long side face M23, a second long side face M24, a first short side face M81, and a second short side face M82 that are connected to the bottom face M11.

The first long side face M23 extending in the Y-axis direction is provided on the +X side of the bottom face M11, and the second long side face M24 extending along the Y-axis direction is provided on the −X side of the bottom face M11. The first short side face M81 is provided on the −Y side of the bottom face M11, and the second short side face M82 is provided on the +Y side of the bottom face M11.

The first long side face M23 and the front face Me intersect at a first long side L21 extending in the Y-axis direction, and the second long side face M24 and the front face Me intersect at a second long side L22 extending in the Y-axis direction. The first short side face M81 and the front face Me intersect at the following sides: a first short side S31 connected to the first long side L21, a second short side S32 connected to the second long side L22, and the third short side S32 that links the first short side S31 and the second short side S32 and extends in the X-axis direction.

Here, a first angle θ9 made by the first long side L21 and the first short side S31 is smaller than a second angle θ10 made by the second long side L22 and the second short side S32.

The second short side face M82 and the front face Me intersect at a fourth short side S41 connected to the first long side L21, at a fifth short side S42 connected to the second long side L22, and at a sixth short side S43 that links the fourth short side S41 and the fifth short side S42 and extends in the X-axis direction.

Here, a third angle θ11 made by the first long side L21 and the fourth short side S41 is smaller than a fourth angle θ12 made by the second long side L22 and the fifth short side S42.

Moreover, as shown in FIG. 11, the second grooves units 13Cb of the third tuning-fork type quartz vibrating pieces 10C each have a bottom face M12, and a first long side face M25, a second long side face M26, a first short side face M91, and a second short side face M92 that are connected to the bottom face M12.

The first long side face M25 and the front face Me intersect at the first long side L31 extending in the Y-axis direction, and the second long side face M26 and the front face Me intersect at the second long side L32 extending in the Y-axis direction. The first short side face M91 and the front face Me intersect at a first short side S51 connected to the first long side L31, at a second short side S52 connected to the second long side L32, and at a third short side S53 that links the first short side S51 and the second short side S52 and extends in the X-axis direction.

Here, a first angle θ13 made by the first long side L31 and the first short side S51 is smaller than a second angle θ14 made by the second long side L32 and the second short side S52. For this reason, a perpendicular bisector Gx of the third short side S53 that links the first short side S51 and the second short side S52 and extends in the X-axis direction shifts to the −X side from the center line Bx in the X-axis direction of the vibrating arm 12C.

As mentioned above, in the third tuning-fork type quartz vibrating piece 10C, the first short side face M81 and the second short side face M82 of the first grooves unit 13Ca and the first short side face M91 of the second grooves unit 13Cb form gentle slopes whose angles with the front face Me are 120° to 160°. Because of this, when forming the grooves excitation electrodes (not illustrated) in the first grooves unit 13Ca and the second grooves unit 13Cb, the photoresist can be applied to the edge portion (see FIG. 3) in uniform thickness on the metal film for electrode and ultraviolet rays are easy to be irradiated onto the photoresist. Therefore, the completed electrode pattern has less occurrence of disconnection etc.

Although in the third embodiment, the case where the short side face and the front and rear faces intersect at the first short side, at the second short side, and at the third short side was explained, the short side face and the front and rear faces may intersect only at the first short side and at the second short side, as explained in the second embodiment. Moreover, although in the third embodiment, the fork part face has the shape of the first fork part 14A explained in the first embodiment, it may have the shape of the first fork part 14B explained in the second embodiment.

<Manufacture Method of the Third Tuning-Fork Type Quartz Vibrating Piece 10C> In the manufacture method of the third tuning-fork type quartz vibrating piece 10C, other steps except Steps S115 to S117 of FIG. 6 are the same as those of the manufacture method of the first tuning-fork type quartz vibrating piece 10A.

In Step S115 shown in FIG. 6, using the exposure apparatus (not illustrated), a pattern of the semifinished product (not illustrated) of the first grooves unit 13Ca and the second grooves unit 13Cb of rectangular shapes drawn on the photomask is exposed on the both surfaces of the quartz wafer 20 to which the photoresist layers are applied. Next, the gold layer exposed from the photoresist layer is wet etched. Subsequently, the chromium layer that is exposed by the gold layer being removed is wet etched. Then, the exposed quartz wafer 20 is wet etched, forming the semifinished product (not illustrated) of the first grooves unit 13Ca and the second grooves unit 13Cb of rectangular shapes.

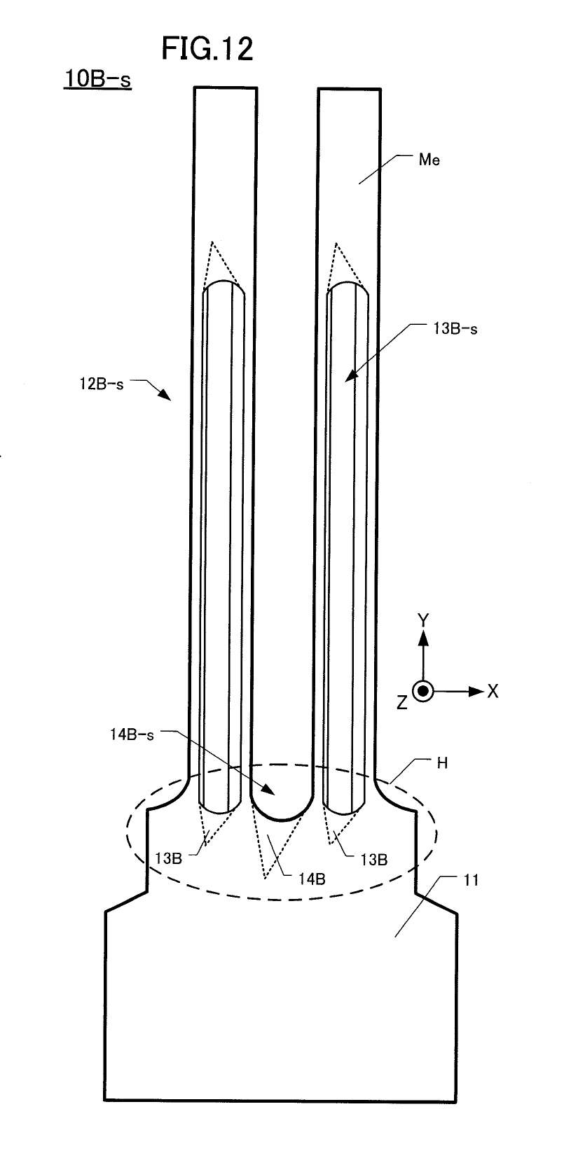

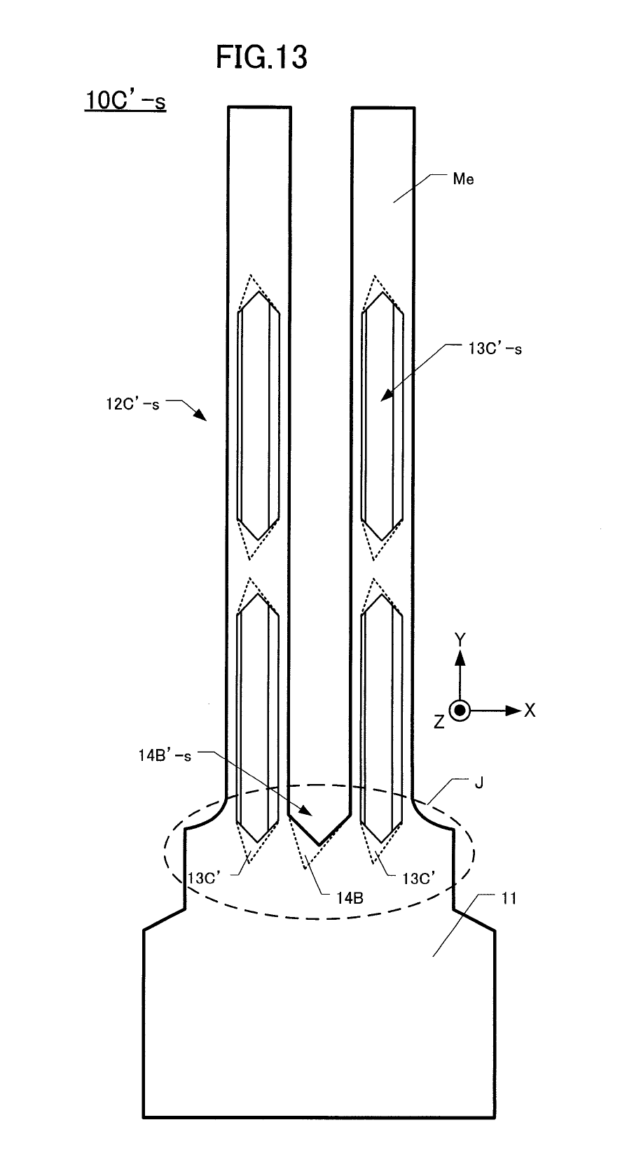

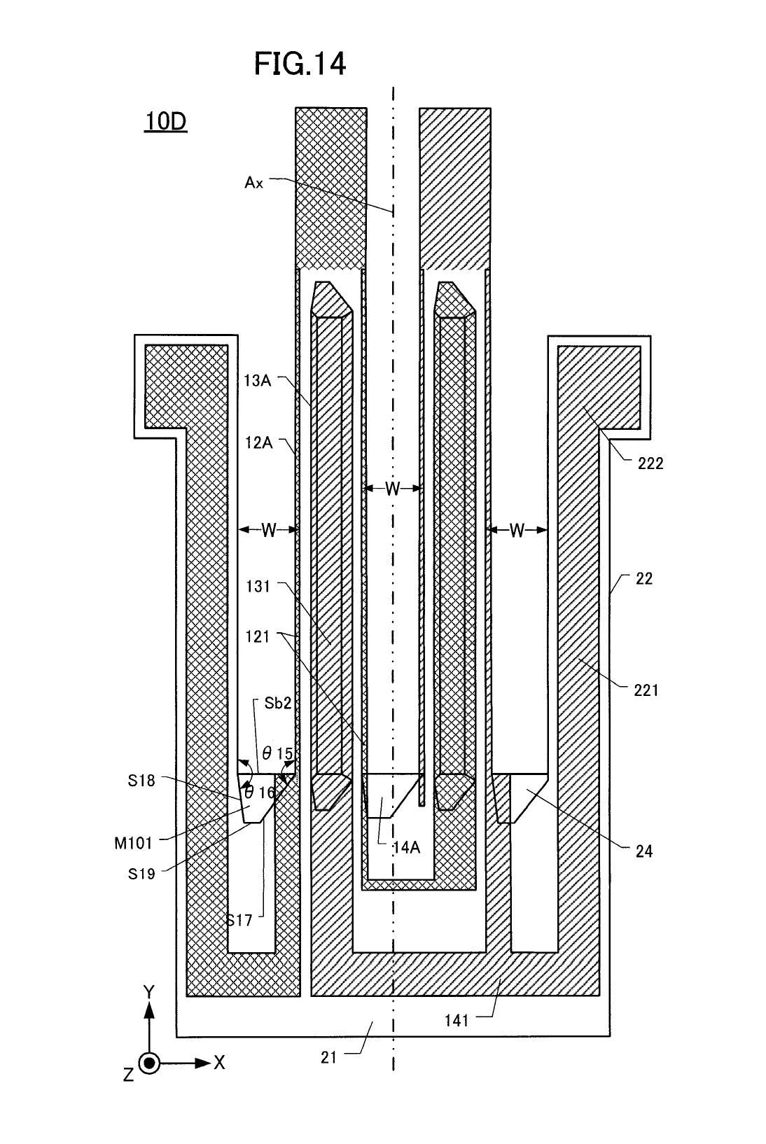

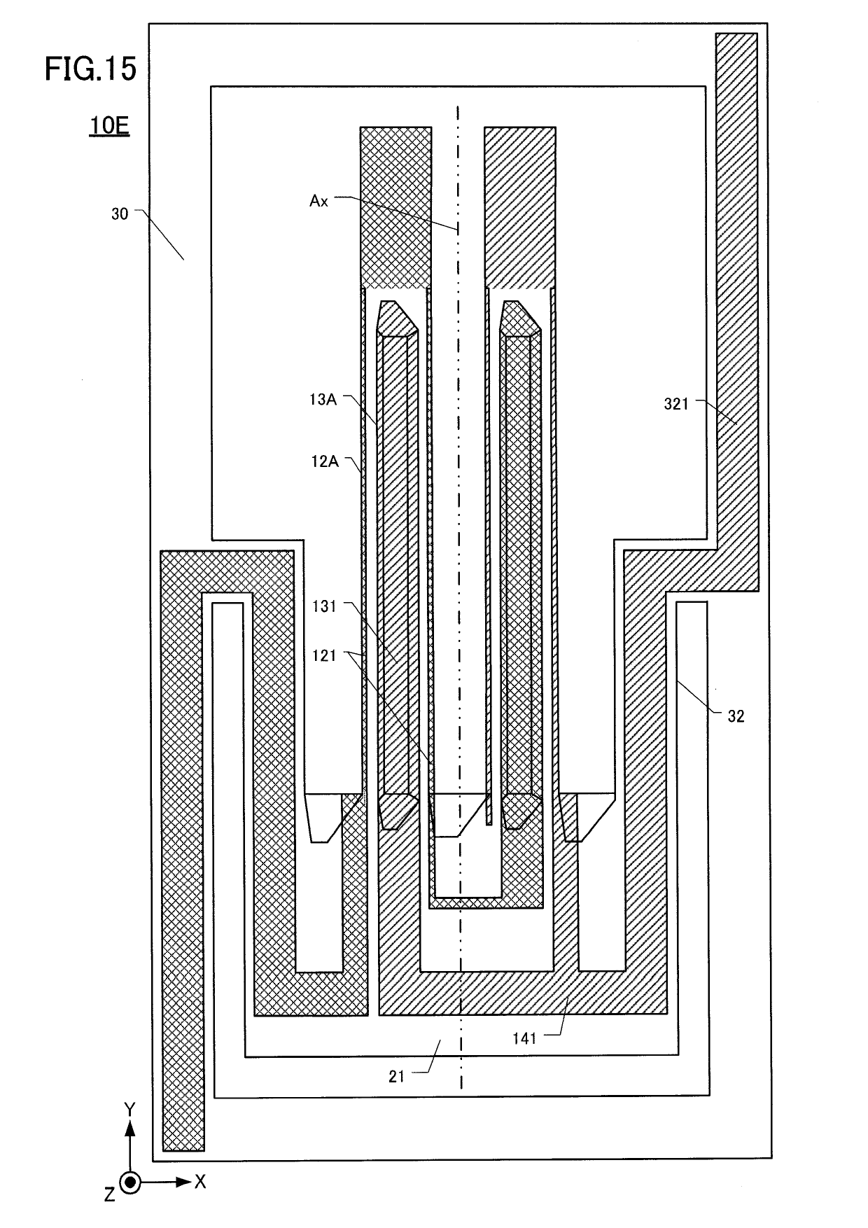

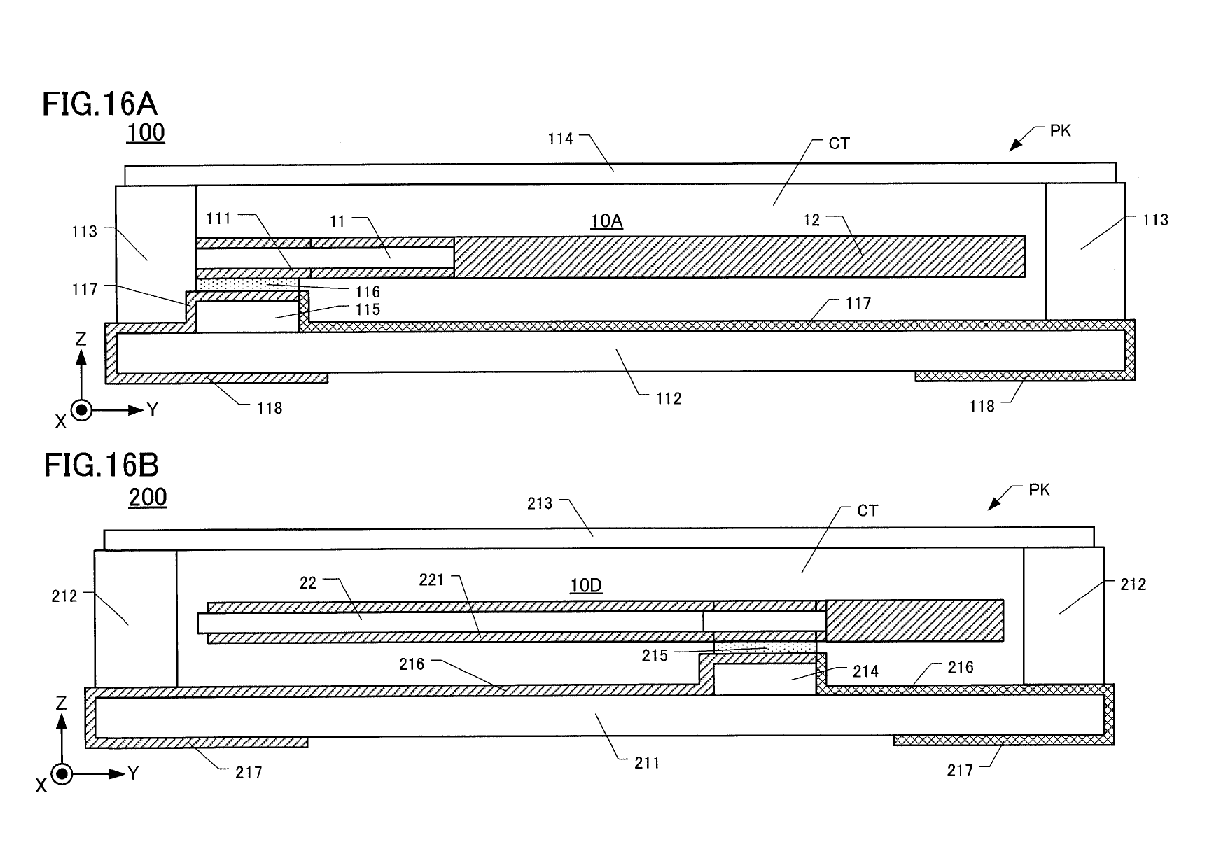

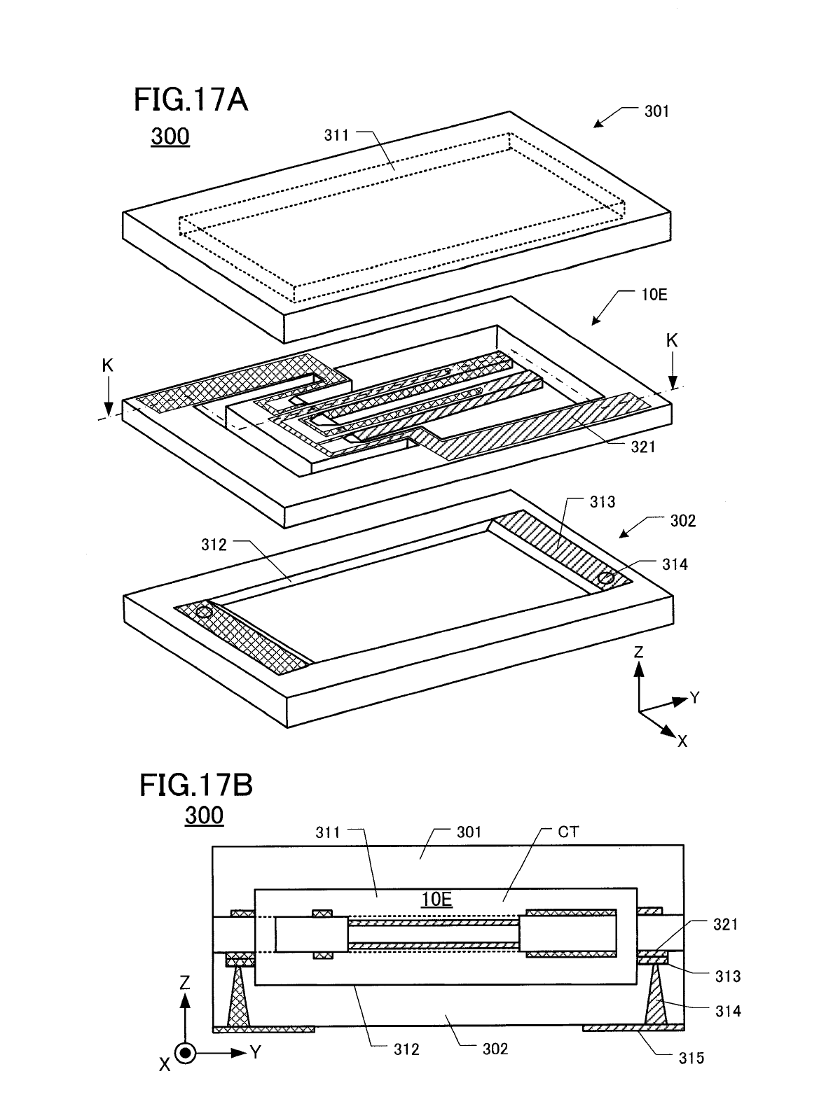

In Step S116, the anticorrosion film and the photoresist that remain in the semifinished product (not illustrated) of the third tuning-fork type quartz vibrating piece 10C are removed. In Step S117, the whole semifinished product (not illustrated) of the third tuning-fork type quartz vibrating piece 10C is wet etched by being immersed in the wet etchant. Thereby, the grooves 13C and the first fork part 14A shown in FIG. 11 are formed. Incidentally, the grooves 13C and the first fork part 14A shown in FIG. 11 may be formed using the mask so that only the first short side face M81 and the second short side face M82 of the first grooves unit 13Ca and the first short side face M91 of the second grooves unit 13Cb that are shown in FIG. 11 may be wet etched.

<First Modification> Regarding the quartz vibrating piece of the first to third embodiments explained so far, as shown by the solid lines of FIG. 7, shapes of their the grooves are rectangles. However, the shape of the grooves formed through Steps S111 to S115 of FIG. 6 is not restricted to a rectangle. Below, a first modification will be explained by taking a modification of the second tuning-fork type quartz vibrating piece 10B of the second embodiment as one example. FIG. 12 is a plan view showing a semifinished product of the second tuning-fork type quartz vibrating piece 10B-s in the first modification.

An intersection shape of a semifinished product of the first fork part 14B-s and the front face Me that were formed by the process up to Step S113 explained in FIG. 6 has a circular arc shape as drawn by a solid line of FIG. 12. This is because the photomask at the time of forming an outline pattern of the second tuning-fork type quartz vibrating piece 10B is formed to be a circular arc. Incidentally, in the process up to Step S113, a semifinished product of the grooves 13B-s shown in FIG. 12 is not formed, and the second tuning-fork type quartz vibrating piece 10B is a planar shape.

By a process of Step S115, short-side facing portions of the semifinished product of the grooves 13B-s are formed to be a circular arc (U-shaped). That is, as drawn by solid lines of FIG. 12, an intersection shape of the semifinished product of the grooves 13B-s and the front face Me has a round rectangular shape with circular arcs on both sides of the Y-axis direction and straight lines on both sides of the X-axis direction. This is because a shape of the groove pattern of the photomask is formed to be a circular arc.

Then, Step S117 is performed in the state that is shown by the solid lines of FIG. 12, and the grooves 13B and the first fork part 14B as shown by dotted lines of FIG. 12 are formed.

Although the first modification is a modification of the second embodiment, an idea of the modification is also applied to the first embodiment. That is, in Steps S113 and S115 explained in FIG. 6, it may be all right that by performing Step S117 in a state where the semifinished product of the first fork part 14B-s and the semifinished product of the grooves 13B-s shown in FIG. 12 have been formed, the grooves 13A and the first fork part 14A (see FIG. 4) that were explained in the first embodiment are formed. Similarly, the idea of the modification is also applied to the third embodiment.

<Second Modification> Below, a second modification will be explained by taking a modification of a third tuning-fork type quartz vibrating piece 10C′ of the third embodiment as one example. FIG. 13 is a plan view showing a semifinished product of the third tuning-fork type quartz vibrating piece 10C′-s in the second modification.

A semifinished product of the first fork part 14C′-s formed by a process up to Step S113 explained in FIG. 6 is in the V-shaped that consists of two straight lines as drawn by solid lines of FIG. 13. This is because the photomask at the time when an outline pattern of the third tuning-fork type quartz vibrating piece 10C′ is formed is formed to be V-shaped. Incidentally, in the process up to Step S113, a semifinished product of the grooves 13C′-s shown in FIG. 13 is not formed, but the third tuning-fork type quartz vibrating piece 10C′ is a planar shape.

By a process of Step S115, short-side facing portions of the semifinished product of the grooves 13C′-s are formed to be V-shaped, as shown by the solid lines of FIG. 13. This is because the shape of the groove pattern of the photomask is formed to be V-shaped.

After that, Step S117 is performed, and the grooves 13C′ and the first fork part 14A as shown by dotted lines of FIG. 13 are formed. Although the second modification is a modification of the third embodiment, an idea of the modification is also applied to the first embodiment and the second embodiment.

<Third Modification> Below, a fourth tuning-fork type quartz vibrating piece 10D of a third modification will be explained. FIG. 14 is a plan view showing the fourth tuning-fork type quartz vibrating piece 10D of the third modification. Its explanation will be done by attaching the same symbol to the same constituent element as that of the first embodiment.

<Entire Configuration of the Fourth Tuning-Fork Type Quartz Vibrating Piece 10D> As shown in FIG. 14, the fourth tuning-fork type quartz vibrating piece 10D has linear symmetry with respect to an axis Ax extending along the Y-axis direction. The fourth tuning-fork type quartz vibrating piece 10D has a base 21 of an almost rectangular shape and the one pair of vibrating arms 12A formed extending from the base 21 to the +Y-axis direction. A pair of grooves 13A is formed on the front faces of the one pair of vibrating arms 12A.

Moreover, the fourth tuning-fork type quartz vibrating piece 10D has a pair of supporting arms 22 formed extending in the +Y-axis direction from the base 21 respectively outside the one pair of vibrating arms 12A. The one pair of supporting arms 22 has an effect of lessening vibration leakage that vibration of the vibrating arms 12A leaks to the outside of the fourth tuning-fork type quartz vibrating piece 10D. Moreover, the one pair of supporting arms 22 has an effect of making a package PK (see FIG. 16B) unsusceptible to an influence of temperature variation of the outside or impact therefrom. Here, the one pair of vibrating arms 12A is configured so that the distance W thereof and the distance W between the vibrating arm 12A and the supporting arm 22 in the X-axis direction may become the same.

Moreover, the supporting arm 22 is such that a widened arm part 222 wider than the width of the supporting arm 22 is formed at a +Y side distal end thereof. The widened arm part 222 is a location that is connected with a linkage electrode 216 (see FIG. 16B) of the package PK. If the widened arm part 222 has a large area, an area of the connection region to which electrically conductive adhesive 215 (FIG. 16B) is applied will become large. Thereby, the connection area becomes larger, so that the fourth tuning-fork type quartz vibrating piece 10D can be placed in the package PK more securely.

The fourth tuning-fork type quartz vibrating piece 10D has second fork parts 24 consisting of the vibrating arms 12A, supporting arms 22, and the base 21 respectively outside the one pair of supporting arms 22 in the X-axis direction. Moreover, in the one pair of grooves 13A, the grooves excitation electrodes 131 of mutually different polarities (shown by oblique lines and by netted lines in FIG. 14) are formed, respectively. On both outsides of the one pair of vibrating arms 12A in the X-axis direction, the side face excitation electrodes 121 are formed, respectively.

Extractor electrodes 221 extending along the Y-axis direction are formed on the one pair of supporting arms 22. The extractor electrode 221 extends as far as the widened arm part 222 in the +Y-axis direction, and extends as far as the base 21 in the −Y-axis direction. Moreover, the extractor electrode 221 is connected to the side face excitation electrode 121 and the grooves excitation electrode 131 through the connection electrode 141.

With this configuration, the extractor electrode 221 is made to conduct electricity to the side face excitation electrode 121 and the grooves excitation electrode 131. When the extractor electrode 221 is connected to external electrodes 217 (see FIG. 16B) through the electrically conductive adhesive 215 (see FIG. 16B), the external electrodes and the excitation electrodes will conduct electricity, respectively, and the vibrating arms 12A of the fourth tuning-fork type piezoelectric vibration piece 10D will vibrate.

<Configuration of the Second Fork Part 24> The second fork part 24 shown in FIG. 14 has two fork part faces M101 that extend obliquely to the center of the Z-axis direction from the front face Me and the rear face Mi, respectively, and a second boundary side Sb formed so that these two fork part faces M101 intersect almost at the central position in the thickness direction of the fourth tuning-fork type quartz vibrating piece 10D. Here, it is desirable that slope angles (see FIG. 5) that the fork part face M101 makes with the front face Me and the rear face Mi are 120° to 160°. According to such a configuration, the connection electrode 141 can be formed in the second fork part 24 without disconnection.

The fork part face M101 and the front face Me intersect at the fourth fork part side S17, at the fifth fork part side S18, and at the third fork part side S18. Here, a third obtuse angle θ15 made by the fourth fork part side S17 and the Y-axis is smaller than a fourth obtuse angle θ16 made by the fifth fork part side S18 and the Y-axis. For this reason, a perpendicular bisector Jx of the sixth fork part side S19 that links the fourth fork part side S17 and the fifth fork part side S18 and extends in the X-axis direction is shifted to the −X side from the center line Kx between the vibrating arm 12A and the supporting arm 22 that are adjacent. The second fork part 24 of the third modification may have the same configuration as that of the first fork part 14B explained in the second embodiment.

<Manufacture Method of the Fourth Tuning-fork Type Quartz Vibrating Piece 10D> In the fourth tuning-fork type quartz vibrating piece 10D of the third modification, the base 21, the vibrating arms 12A, and the one pair of supporting arms 22 can be formed in Step S113 of FIG. 6 explained in the first embodiment. The second fork part 24 can be formed by the same process as of the first fork part 14A of the first embodiment. That is, by Step S113 and Step S117 of FIG. 6 that were explained in the first embodiment, the second fork part 24 shown in FIG. 14 can be formed.

<Fourth Modification> Below, a fifth tuning-fork type quartz vibrating piece 10E of a fourth modification will be explained referring to FIG. 15. FIG. 15 is a plan view showing the fifth tuning-fork type quartz vibrating piece 10E of the fourth modification. Its explanation will be given attaching the same symbol to the same constituent element as that of the third modification.

As shown in FIG. 15, the fifth tuning-fork type piezoelectric vibration piece 10E is of almost the same configuration as that of the third modification. The fifth tuning-fork type piezoelectric vibration piece 10E has a pair of supporting arms 32 formed extending in the +Y-axis direction from the excitation base 21 respectively outside the one pair of vibrating arms 12A in the X-axis direction. Moreover, the fifth tuning-fork type piezoelectric vibration piece 10E further has an outer frame part 30 of a rectangular shape outside it. This outer frame part 30 is linked to the excitation base 21 through the one pair of supporting arms 32.

Extraction electrodes 321 are formed on the front and rear faces of the one pair of supporting arms 32 in the fifth tuning-fork type piezoelectric vibration piece 10E. The extractor electrodes 321 are formed extending as far as one corner (+X side, +Y side) of the outer frame part 30 and extending as far as the other corner (−X side, −Y side) of the outer frame part 30, respectively. Moreover, the extractor electrodes 321 are connected to the side face excitation electrode 121 and the grooves excitation electrode 131 through the connection electrode 141.

If the extractor electrodes 321 are connected to external electrodes 315 (see FIG. 17) a through electrode 314 (see FIG. 17) with such a configuration, external electrodes 315 and the excitation electrode will conduct electricity, respectively, and the vibrating arms 12A of the fifth tuning-fork type piezoelectric vibration piece 10E will vibrate.

The frame 30 of the fifth tuning-fork type quartz vibrating piece 10E of the fourth modification can be formed simultaneously with the base 21, the vibrating arms 12A, etc. in Step S113 of FIG. 6 explained in the first embodiment.

<First Piezoelectric Device> A piezoelectric vibrator 100 using the first tuning-fork type quartz vibrating piece 10A explained in the first embodiment will be explained as a first piezoelectric device. FIG. 16A is a side view of the piezoelectric vibrator 100 having the first tuning-fork type quartz vibrating piece 10A.

As shown in FIG. 16A, the piezoelectric vibrator 100 is equipped with the package PK having a cavity CT that is constructed with a base plate 112, a wall 113, and a lid 114. The package PK stores the first tuning-fork type quartz vibrating piece 10A in the cavity CT. The base plate 112 and the wall 113 are formed, for example from a piezoelectric crystal, ceramic, or glass. The lid 114 is made up of a piezoelectric crystal, planar metal of Fe—Ni—Co alloy (kovar), glass, or other materials. The inside of the cavity CT is hermetically sealed with nitrogen gas, vacuum, etc. by a technique of seam welding etc.

Moreover, a pedestal 115 is provided on a −Y side of the base plate 112 so as to contact the base plate 112 and the wall 113. The pedestal 115 is also formed with a piezoelectric crystal, ceramic, glass, or the like similarly to the base plate 112 and the wall 113. The first tuning-fork type quartz vibrating piece 10A is fixed to the pedestal 115 through the electrically conductive adhesive 116 with its base 11 placed on the pedestal 115.

The base electrodes 111 (see FIG. 1) formed in the base 11 are connected to the external electrodes 118 through the electrically conductive adhesive 116 and linkage electrodes 117, respectively. The linkage electrodes 117 each go through between the base plate 112 and the wall 113 and are connected to the one pair of external electrodes 118 provided on a bottom face of the base plate 112. If such a configuration is adopted, when an alternating voltage is impressed to the one pair of external electrodes 118, the vibrating arms 12 of the first tuning-fork type quartz vibrating piece 10A will be excited.

Although the piezoelectric vibrator 100 using the first tuning-fork type quartz vibrating piece 10A was explained, the tuning-fork type quartz vibrating piece explained in the second and third embodiments or the first and second modifications may be used instead of the first tuning-fork type quartz vibrating piece 10A.

<Second Piezoelectric Device> A piezoelectric vibrator 200 using the fourth tuning-fork type piezoelectric vibration piece 10D that was explained in the third modification as the second piezoelectric device will be explained. FIG. 16B is a side view of the piezoelectric vibrator 200 having the fourth tuning-fork type piezoelectric vibration piece 10D.

As shown in FIG. 16B, the piezoelectric vibrator 200 is equipped with the package PK having the cavity CT that is constructed with a base plate 211, a wall 212, and a lid 213. The package PK stores the fourth tuning-fork type piezoelectric vibration piece 10D in the cavity CT. A pedestal 214 is provided almost in the central part of the base plate 211 in the Y-axis direction. The pedestal 214 is also formed with a piezoelectric crystal, ceramic, glass, or the like similarly to the base plate 211 and the wall 212. The fourth tuning-fork type piezoelectric vibration piece 10D is fixed on the pedestal 214 through the electrically conductive adhesive 215 with the widened arm part 222 of the supporting arm 22 placed on the pedestal 214. The extractor electrode 221 (see FIG. 14) formed in the supporting arm 22 is connected to the external electrode 217 through the electrically conductive adhesive 215 and the linkage electrode 216.

<Third Device> A piezoelectric vibrator 300 using the fifth tuning-fork type piezoelectric vibration piece 10E that was explained in the fourth modification as the third piezoelectric device will be explained referring to FIG. 17. FIG. 17A is an exploded perspective view of the piezoelectric vibrator 300 having the fifth tuning-fork type piezoelectric vibration piece 10E, and FIG. 17B is a K-K cross-sectional view of the piezoelectric vibrator 300 having the fifth tuning-fork type piezoelectric vibration piece 10E.

As shown in FIG. 17A, the piezoelectric vibrator 300 consists of a top lid part 301, a lowermost base plate 302, and the fifth tuning-fork type piezoelectric vibration piece 10E of a central part. Each of the lid part 301, the base plate 302, and the fifth tuning-fork type piezoelectric vibration piece 10E is formed from a piezoelectric material. The lid part 301 has a concave part 311 for lid formed by the wet etching on its one face facing the fifth tuning-fork type piezoelectric vibration piece 10E. The base plate 302 has a concave part 312 for base formed by the wet etching on its one face facing the fifth tuning-fork type piezoelectric vibration piece 10E. Therefore, the cavity CT is formed with the concave part 311 for lid and the concave part 312 for base.

Moreover, base connection electrodes 313 are provided on both sides of the +Z side base plate 302 in the Y-axis direction, respectively. Under the base connection electrodes 313, the through electrodes 314 are provided, respectively. Furthermore, as shown in FIG. 17B, one of the through electrodes 314 is connected to an external electrode 315, and the other of the through electrodes 314 is connected to the external electrode 315.

As shown in FIG. 17B, the piezoelectric vibrator 300 has the fifth tuning-fork type piezoelectric vibration piece 10E in its center, to whose rear face the base plate 302 is bonded, and to whose front face the lid part 301 is bonded. That is, it has a configuration where the lid part 301 is sealed to the fifth tuning-fork type piezoelectric vibration piece 10E and the base plate 302 is sealed to the fifth tuning-fork type piezoelectric vibration piece 10E by a siloxane bond (Si—O—Si) technology.

With such a configuration, in the fifth tuning-fork type piezoelectric vibration piece 10E, the extractor electrode 321 conducts electricity to the external electrode 315 through the base connection electrode 313 and the through electrode 314. It may be all right that the lid part 301, the fifth tuning-fork type piezoelectric vibration piece 10E, and the base plate 302 may be bonded, for example, by an anodic bonding technology etc.

As mentioned above, although the optimal embodiments of the present invention were explained in detail, the present invention can be carried out by adding various changes and modifications within the scope of the technology as is clear for persons skilled in the art. For example, the present invention can be applied to a piezoelectric oscillator having an IC with an oscillation circuit incorporated is placed, other than the piezoelectric vibrator.

What is claimed is:

1. A method for manufacturing a tuning-fork type quartz vibrating piece that is made of a quartz material and has a base having front and rear faces, a pair of vibrating arms extending in a Y-axis direction from the base, and grooves extending in the Y-axis direction on front and rear faces of the one pair of vibrating arms, comprising:
a photolithography step of applying a resist to an anticorrosion film formed on the quartz material, and exposing a region thereof that corresponds to the base, the vibrating arms, and the grooves by exposing the resist;
a first etching step of forming an outline of the tuning-fork type quartz vibrating piece by etching the anticorrosion films other than the region that corresponds to the base, the vibrating arms, and the groves and by etching the quartz material;
a removal step of removing the anticorrosion film and the resist that remain on the quartz material; and
a second etching step of etching at least one of a first fork part formed between the one pair of vibrating arms and the base, and a base-side end face of the grooves by immersing the quartz material in an etchant after the removal step.

2. The method for manufacturing the tuning-fork type quartz vibrating piece according to claim 1,
wherein the first etching step and the second etching step use the same temperature and the same etchant, and an etching time of the second etching step is shorter than an etching time of the first etching step.

3. The method for manufacturing the tuning-fork type quartz vibrating piece according to claim 1,
wherein in the second etching step, the whole front and rear faces of the tuning-fork type quartz vibrating piece exposed by the removal process are immersed in the etchant.

4. The method for manufacturing the tuning-fork type quartz vibrating piece according to claim 2,
wherein in the second etching step, the whole front and rear faces of the tuning-fork type quartz vibrating piece exposed by the removal process are immersed in the etchant.

5. The method for manufacturing the tuning-fork type quartz vibrating piece according to claim 1,
wherein in the second etching step, at least one of the first fork part and the end face in the tuning-fork type quartz vibrating piece is covered with a mask and is immersed in the etchant.

6. The method for manufacturing the tuning-fork type quartz vibrating piece according to claim 2,
wherein in the second etching step, at least one of the first fork part and the end face in the tuning-fork type quartz vibrating piece is covered with a mask and is immersed in the etchant.

7. A piezoelectric device having a package having a cavity for storing the tuning-fork type piezoelectric vibration piece manufactured according to claim 1.

8. A piezoelectric device having a package having a cavity for storing the tuning-fork type piezoelectric vibration piece manufactured according to claim 2.

9. A piezoelectric device having a package having a cavity for storing the tuning-fork type piezoelectric vibration piece manufactured according to claim 3.

10. A piezoelectric device having a package having a cavity for storing the tuning-fork type piezoelectric vibration piece manufactured according to claim 5.

11. A piezoelectric device that is equipped with a lid plate having a first recess part and a base plate having a second recess part and sandwiches the tuning-fork type piezoelectric vibrating piece manufactured by claim 1 with the lid plate and the base plate.

12. A piezoelectric device that is equipped with a lid plate having a first recess part and a base plate having a second recess part and sandwiches the tuning-fork type piezoelectric vibrating piece manufactured by claim 2 with the lid plate and the base plate.

13. A piezoelectric device that is equipped with a lid plate having a first recess part and a base plate having a second recess part and sandwiches the tuning-fork type piezoelectric vibrating piece manufactured by claim 3 with the lid plate and the base plate.

14. A piezoelectric device that is equipped with a lid plate having a first recess part and a base plate having a second recess part and sandwiches the tuning-fork type piezoelectric vibrating piece manufactured by claim 5 with the lid plate and the base plate.
